(19) United States
(12) Patent Application Publication
(10) Pub. No.: US 2012/0043577 A1
(43) Pub. Date: Feb. 23, 2012

(54) CURABLE SILICONE RESIN COMPOSITION AND LIGHT-EMITTING DIODE DEVICE USING THE SAME

(75) Inventors: Katsuyuki IMAZAWA, Annaka-shi (JP); Tsutomu KASHIWAGI, Annaka-shi (JP)

(73) Assignee: SHIN-ETSU CEMICAL CO., LTD., Tokyo (JP)

(21) Appl. No.: 13/212,532

(22) Filed: Aug. 18, 2011

(30) Foreign Application Priority Data
Aug. 23, 2010 (JP) 2010-185964

(51) Int. Cl. H01L 33/52; C08L 83/04; C08L 83/07; C08K 3/36

(52) U.S. Cl. 257/99; 524/493; 257/E33.059

(57) ABSTRACT

This invention discloses a curable silicone resin composition used for sealing a light-emitting diode device, comprising at least a silicone resin having a refractive index of 1.50˜1.55 after curing and a silicon oxide filler having an average particle diameter of 1˜10 μm dispersed uniformly in the said silicone resin at the concentration of 1˜30 mass % and a light-emitting diode device using the same.

### TECHNICAL FIELD

The present invention relates to a sealing resin composition of photo-semiconductor chip and a light-emitting diode (LED) device using the same, and in particular relates to a curable silicone resin composition which contains a silicon oxide filler having a specific particle diameter within a certain definite range of concentration, and a light-emitting diode device which uses the said composition as a sealing resin.

### BACKGROUND OF THE INVENTION

Regarding a coating-protective resin composition of photo-semiconductor chip such as a light-emitting diode (LED) or the like, it is required that the cured material thereof is transparent. Therefore, generally, resins obtained by using epoxy resins such as bisphenol A epoxy resin or alicyclic epoxy resin and an acid anhydride curing agent are used (Patent documents 1 and 2). However, these transparent epoxy resins had disadvantages where light durability was poor and coloring occurred due to deterioration by light since light transmittance is poor against light of shorter wavelength.

Consequently, a coating-protective resin composition of photo-semiconductor chip consisting of an organic compound which has at least two carbon-carbon double bonds having reactivity with an SiH group within a molecule, a silicone compound which has at least two SiH groups within a molecule and a hydrosilylation catalyst are proposed (Patent documents 3 and 4). However, such silicone cured material, especially a silicone composition having a refractive index of 1.45 or less after curing had a disadvantage where sulfurized gas existing in the storage environment and the use environment is permeated since it has higher gas permeability in comparison with epoxy resin used conventionally.

The above disadvantage causes a problem in that the sulfurized gas which permeated the silicone cured material reacts with the silver on the silver-plated surface of the lead frame which is a substrate of the light-emitting diode device, then the silver changes to silver sulfide and as a result the silver-plated surface blackens. In addition, there was another disadvantage in that since the refractive index of optical crystal of a compound semiconductor used as a chip is high, light reflects at the interface between the sealing resin and the optical crystal and as a result light-emitting luminance decreases.

By the way, the gas permeability of silicone resin cured material is generally 20 g/m²·24 hours or more. In particular, the gas permeability of the silicone resin cured material having a refractive index of 1.45 or less is 50 g/m²·24 hours or more, which is much higher. Therefore, the silicone resin cured material having a refractive index of 1.45 or less easily permeates the sulfurized gas existing in the external environment. Furthermore, sulfurized gas exists in the atmosphere as a sulfur oxide (SOx) and also there is sulfurized gas coming from a sulfur constituent generally contained in packing materials such as cardboard boxes.

On the other hand, the lead frame surface of LED package is generally silver-plated from a viewpoint of light reflection efficiency. If the light-emitting diode device having a silver-plated lead frame sealed with the silicone resin cured material having a refractive index of 1.45 or less is left in the atmosphere where sulfurized gas exists, the reaction of the sulfurized gas which permeated the silicone resin and the silver progresses as previously mentioned. As a result, the silver sulfide is generated on the lead frame surface. Since the surface of the LED package substrate is blackened by this reaction, the light reflection efficiency considerably decreases. This is one of the factors that makes it impossible to maintain reliability over long periods which should be provided by the light-emitting diode device.

In addition, the refractive index of the optical crystal of compound semiconductors used as a chip is 2.0 or more, which is high. Therefore, in cases where the sealing resin having a refractive index of 1.50 or less is used, the difference of the refractive index between the optical crystal and the sealing resin is large, the light reflection index at the interface increases and as a result the emission luminance decreases. Although this problem can be improved by using a silicone resin having a refractive index of 1.50 or more, the improvement was not sufficient for the high luminance LED market required from the field of general lighting or the like.

In order to solve the above problem, a method of using a silicone composition is proposed wherein gas permeability is comparatively lower, interfacial reflection is reduced and refractive index is 1.45 or more after curing (Patent document 5). However, at present, as LED is starting to be used for general lighting, the further improvement of emission luminance has come to be required.

### PRIOR ART DOCUMENTS

### Patent Document

[Patent document 1] Japanese Patent 3241338
[Patent document 2] Japanese Unexamined Patent Publication Tokkaihei 7-25987
[Patent document 3] Japanese Unexamined Patent Publication Tokkai 2002-327126
[Patent document 4] Japanese Unexamined Patent Publication Tokkai 2002-338833
[Patent document 5] Japanese unexamined Patent Publication Tokkai 2004-29280

### SUMMARY OF THE INVENTION

### Problems to be Solved by the Invention

Therefore, the first object of the present invention is to provide a curable silicone resin composition suitable as a sealing material for a light-emitting diode device, wherein not only the gas permeability is low, but also the interfacial reflection is reduced.

The second object of the present invention is to provide a light-emitting diode device, which has the excellent light-emitting luminance and is available for general lighting.

### Means to Solve the Problems

The inventors found, as a result of extensive studies to achieve the above objects, that the luminance can be improved by dispersing uniformly a silicon oxide filler having a specific average particle diameter in a silicone resin at the concentration of 1˜30 mass %, thereby achieving the present invention.

Therefore, the present inventions are a curable silicone resin composition used for sealing the light-emitting diode device, comprising at least a silicone resin having a refractive index of 1.50˜1.55 after curing and a silicon oxide filler having an average particle diameter of 1˜10 μm dispersed uniformly in the said silicone resin at the concentration of 1˜30 mass %; and a light-emitting diode device using the said resin composition as a sealing resin.

It is preferable in the present invention that the refractive index of the above silicon oxide filler is 1.50˜1.56. It is preferable that the silicone resin having a refractive index of 1.50˜1.55 after curing is comprised of an addition curable silicone resin composition containing (A) an organosilicon compound having a noncovalent carbon-carbon double bond, (B) organohydrogenpolysiloxane and (C) a platinum catalyst, as an essential component.

### Effect of the Invention

The curable silicone resin composition of the present invention is suitable as a sealing resin for the light-emitting diode device, since not only the gas permeability thereof after curing is low, but also the interfacial reflection is reduced, and the light-emitting diode device of the present invention obtained by using this is suitable for general lighting since the luminance thereof is high enough.

### BRIEF DESCRIPTION OF THE DRAWINGS

FIG. 1 An explanatory cross-section drawing showing an example of light-emitting diode devices of the present invention.

FIG. 2 A graph which shows wavelength dependence of light transmission in each case where the amount of silicon oxide which is contained in the silicone resin was changed.

### EMBODIMENTS FOR CARRYING OUT THE INVENTION

The present invention will be illustrated in greater detail by reference to drawings. In the present invention, silicon oxide filler having an average particle diameter of 1˜10 μm is dispersed uniformly in the silicone resin having a refractive index of 1.50˜1.55 after curing, at the concentration of 1˜30 mass %. In this case, it is preferable to use a silicon oxide filler having a refractive index of 1.50˜1.56 which is nearly equal to the refractive index of the silicone resin after curing, as a silicon oxide filler. In particular, it is preferable to use a silicon oxide filler having a refractive index of 1.52˜1.56.

By doing this, the light transmission of silicon oxide filler-containing resin can be 80% or more (See FIG. 2). Consequently, the transparancy of the sealing resin can be substantially maintained and the deterioration of the light emitting luminance due to adding the silicon oxide filler can be prevented. In addition, since a light scattering effect can be obtained by dispersing the silicon oxide filler, it can be thought that the light-emitting amount taken out from the LED package increases, and as a result light-emitting luminance improves.

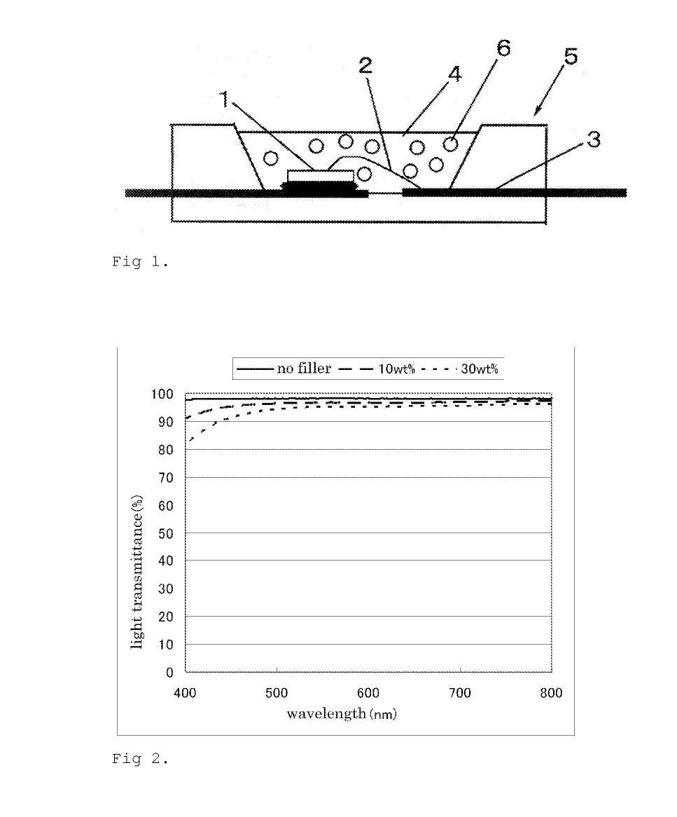

FIG. 1 is an explanatory cross-sectional drawing showing an example of a light-emitting diode device of the present invention. Numeral 1 represents a LED chip, numeral 2 represents a conductive wire, numeral 3 represents a silver-plated lead frame, numeral 4 represents a cured body of the curable silicone resin composition, numeral 5 represents a mold package and numeral 6 represents a silicon oxide filler.

The silicon oxide filler used in the present invention is required to have an average particle diameter of 1˜10 μm. It is preferable to be within the range of 1˜6 μm. If the average particle diameter is 1 μm or less, since resin viscosity increases, the amount added to the resin is limited, which is not preferable. On the other hand, if the average particle diameter of the silicon oxide filler is 10 μm or more, precipitation may occur when stored for a long time as a silicone resin composition before curing and storage stability cannot be kept, which is not preferable.

In addition, in the present invention, it is necessary to disperse the silicon oxide filler in the silicone resin of the sealing resin so that the concentration can be 1˜30 mass %. In particular, it is preferable to disperse it so that the concentration can be 5˜15 mass %. By doing this, the light emitting luminance can be improved about 10% in comparison with cases where the filler is not filled up. If the fill of filler is 1 mass % or less, sufficient light scattering effects cannot be obtained. Therefore, higher light-emitting luminance cannot be obtained in comparison with cases where the filler is not filled up. In addition, if it is 30 mass % or more, transparency of the resin cannot be maintained, therefore, the light-emitting luminance may deteriorate as a result.

The silicone resin used in the present invention can be selected as appropriate from among silicone resins having a refractive index of 1.50˜1.55 after curing. In the present invention, in particular, the addition curable silicone resin composition comprising, as essential components, (A) an organic silicone compound having a noncovalent carbon-carbon double bond, (B) organohydrogen polysiloxane and (C) a platinum catalyst is suitably used.

### Component (A):

It is preferable to use the organopolysiloxane represented by the following average composition formula (1) as an organosilicone compound of the above component A.

Average composition formula (1):

R¹R²R³SiO(R⁴R⁵SiO)ₐ—(R⁶R⁷SiO)_{b}—SiR¹R²R³

R¹ in the above formula represents a monovalent hydrocarbon group having a noncovalent carbon-carbon double bond. R²˜R⁷ represent identical or different kinds of monovalent hydrocarbon groups respectively. It is preferable that, among these, R⁴˜R⁷ are monovalent hydrocarbon groups excluding an aliphatic unsaturated bond, and R⁶ and/or R⁷ is an aromatic monovalent hydrocarbon group. a and b are integers satisfying the relation of 0≦a+b≦500, preferably integers of 10≦a+b≦500. a is o≦a≦500, preferably an integer of 10≦a≦500. b is 0≦b≦250, preferably an integer of 0≦b≦150.

The above R¹ has an aliphatic unsaturated bond typified by an alkenyl group having 2˜8, in particular 2˜6 carbon atoms. As for the R²˜R⁷, groups having 1˜20, in particular 1˜10 carbon atoms are suitable. Specific examples thereof are an alkyl group, an alkenyl group, an aryl group and an aralkyl group. Among these, an alkyl group, an aryl group and an aralkyl group or the like, which do not have an aliphatic unsaturated bond like an alkenyl group and so on, are particularly preferable as R⁴˜R⁷. In addition, it is preferable that R⁶ and/or R⁷ is an aromatic monovalent hydrocarbon group like an aryl group having 6˜12 carbon numbers such as phenyl group and a tolyl group.

The organopolysiloxane of the above average composition formula (1) can be obtained by an alkali equilibrating reaction of cyclic diorganopolysiloxanes such as cyclic diphenyl polysiloxane and cyclic methylphenyl polysiloxane, which form a principal chain, with disiloxanes such as diphenyl tetravinyldisiloxane and divinyl tetraphenyldisiloxane, which form a terminal group. In this case, it is preferable that a silanol group and a chlorine atom are not contained.

As specific examples of organopolysiloxane of the above average composition formula (1), the following ones can be cited.

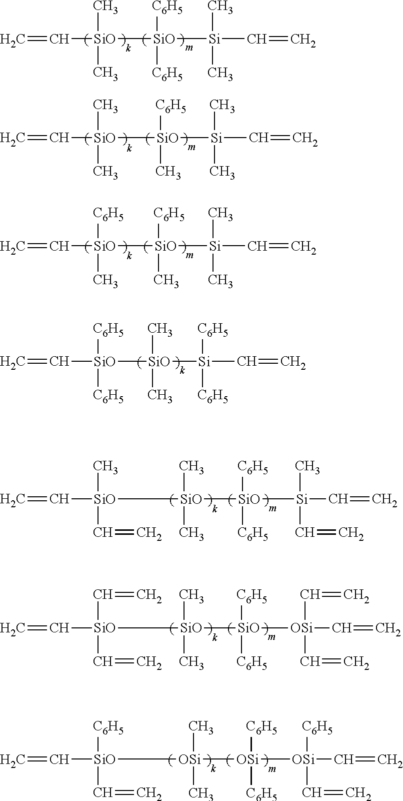

In the above formulae, k and m are integers satisfying 0≦k+m≦500, preferably 5≦k+m≦250, and are integers satisfying 0≦m/(k+m)≦0.5.

Organopolysiloxane having a three-dimensional network structure, which contains 3 functional siloxane units and 4 functional siloxane units or the like can be used together, if necessary, with organopolysiloxane having a straight chain structure of the above average composition formula (1) as the above component (A).

It is preferable that the content of the groups containing a noncovalent carbon-carbon double bond in the component (A) is 1˜50 mol % relative to all monovalent hydrocarbon groups, in particular 2˜40 mol % is more preferable, 5˜30 mol % is optimum. If the content of the groups containing a noncovalent carbon-carbon double bond is less than 1 mol %, cured material cannot be obtained. If it is more than 50 mol %, mechanical characteristics may deteriorate, which is not preferable.

In addition, it is preferable that 0˜95 mol % of aromatic groups is contained in the component (A) relative to all monovalent hydrocarbon groups. It is more preferable to contain 10˜90 mol %. It is especially preferable to contain 20˜80 mol %. If the appropriate amount of aromatic groups is contained in the resin, there is an advantage where not only mechanical characteristics of a cured resin improve but also the preparation of the resin becomes easier. Furthermore, the refractive index can be controlled by introducing the aromatic groups, which is another advantage.

### Component (B):

The organohydrogenpolysiloxane used as the component (B) in the present invention, having two or more hydrogen atoms which bond directly to silicon atoms within a molecule, works as a cross linking agent. A cured material is formed by performing addition reaction of the SiH groups of the said component (B) with the groups having the noncovalent carbon-carbon double bond such as a vinyl group (typically an alkenyl group) in the above component (A).

In cases where the organohydrogenpolysiloxane containes the aromatic hydrocarbon group, an organosilicon compound having the noncovalent carbon-carbon double bond in the above component (A) has high compatibility even if it has a high refractive index. Therefore, a transparent cured material can be obtained. Accordingly, it is preferable to use the organohydrogenpolysiloxane having an aromatic monovalent hydrocarbon group as the organohydrogenpolysiloxane of a part or all parts of the component (B) used in the present invention.

In the present invention, an organohydrogenpolysiloxane having a glycidyl structure can be used as a part or all parts of the organohydrogenpolysiloxane of the component (B). Thus, a sealing resin composition for the photo-semiconductor having high adhesive properties to a substrate can be obtained by providing the organohydrogenpolysiloxane of the component (B) with the glycidyl structure.

The organohydrogenpolysiloxane of the component (B) used in the present invention is not limited to the one above. Examples are 1,1,3,3-tetramethyldisilloxane, 1,3,5,7-tetramethylcyclotetrasiloxane, tris(dimethylhydrogensiloxy)methylsilane, tris(dimethylhydrogensiloxy)phenyl silane, 1-glycidoxy, propyl-1,3,5,7-tetramethylcyclotetrasiloxane, 1,5-glycidoxypropyl-1,3,5,7-tetramethylcyclotetrasiloxane, 1-glycidoxypropyl-5-trimethoxy silyl ethyl-1,3,5,7-tetramethylcyclotetrasiloxane, methylhydrogenpolysiloxane both ends thereof are terminated with trimethylsiloxy group, dimethylsiloxane/methylhydrogensiloxane copolymer both ends thereof are terminated with trimethylsiloxy group, dimethyl polysiloxane both ends thereof are terminated with dimethylhydrogen siloxy group, dimethylsiloxane/methylhydrogensiloxane copolymer both ends thereof are terminated with dimethylhydrogensiloxy group, methylhydrogensiloxane/diphenylsiloxane copolymer both ends thereof are terminated with trimethylsiloxy group, methyl hydrogensiloxane.diphenylsiloxane.dimethylsiloxane copolymer both ends thereof are terminated with trimethyl siloxy group, trimethoxy silane polymer, a copolymer consisting of a (CH₃)₂HSiO_{1/2} unit and a SiO_{4/2} unit, and a copolymer consisting of a (CH₃)₂HSiO_{1/2} unit, a SiO_{4/2} unit and a (C₆H₅)SiO_{3/2} unit or the like.

Furthermore, the organohydrogenpolysiloxane obtained by using the unit represented by the following structure can be used for the present invention.

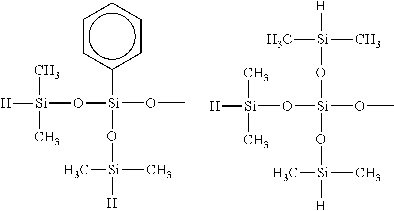

Examples of such organohydrogenpolysiloxane are as follows.

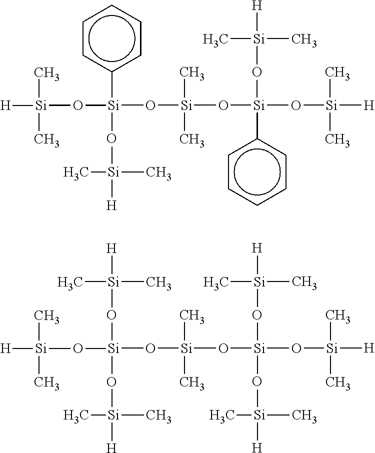

The molecular structure of such organohydrogen polysiloxane may be straight-chain, cyclic, branched or three-dimensional network. It is preferable that the number of silicon atoms within a molecule (or the polymerization degree) is two or more. 2˜1,000 is more preferable. In particular it is preferable to use organohydrogenpolysiloxane having 2˜300 silicon atoms.

As for the blending amount of organohydrogenpolysiloxane as the component (B) used in the present invention, it is preferable that silicon atom-bonded hydrogen atom (SiH group) is 0.75˜2.0 per group having noncovalent carbon-carbon double bond (typically alkenyl group) of the component (A).

### Component (C):

A platinum catalyst is used as the above component (C) in the present invention. Examples of the platinum catalyst are chloroplatinic acid, alcohol-modified chloroplatinic acid, platinum complex having a chelate structure. These may be used alone, or two or more kinds of them may be used in combination. The blending amount of these catalyst components may be the so-called catalytic amount, that is, the effective amount for curing. Usually, it is used within the range of 0.1˜500 ppm, in particular 0.5˜100 ppm in terms of the mass of metals which belong to the platinum group, relative to 100 mass parts of the total amount of the above components (A) and (B).

### Other Component (D):

It is preferable that the addition curable silicone resin composition of the present invention has the above-mentioned components (A)-(C) as an essential component, however, various kinds of silane coupling agents may be further added if necessary. Examples of such silane coupling agents are vinyltrimethoxysilane, vinyltriethoxysilane, 2-(3,4-epoxycyclohexyl)ethyltrimethoxysilane, 3-glycidoxypropyltrimethoxysilane, 3-glycidoxypropylmethyldiethoxysilane, 3-glycidoxypropyltriethoxysilane, 3-methacryloxypropylmethyldimethoxysilane, 3-methacryloxypropyltrimethoxysilane, 3-methacryloxypropylmethyldiethoxysilane, 3-methacryloxypropyltriethoxysilane, N-2(aminoethyl)3-aminopropylmethyldimethoxysilane, N-2(aminoethyl)3-aminopropyltrimethoxysilane, N-2(aminoethyl)3-aminopropyltriethoxysilane, 3-aminopropyltrimethoxysilane, 3-aminopropyltriethoxysilane, N-phenyl-3-aminopropyltrimethoxysilane, 3-mercaptopropyltrimethoxysilane or the like and trimethoxysilane, tetramethoxysilane and oligomer thereof or the like. These silane coupling agents can be used alone or two or more kinds of them can be used by mixture.

It is preferable that the blending amount of the above silane coupling agents is 10 mass % or less relative to the total composition (0˜10 mass %). In particular, it is preferable to blend 5 mass % or less (0˜5 mass %).

In addition, antioxidants such as BHT and vitamin B; a widely-known discoloration inhibitor such as organophosphorous discoloration inhibitor; a light degradation inhibitor such as hindered amine; reactive diluents such as vinyl ethers, vinyl amides, epoxy resins, oxetanes, allyl phthalates and adipic acid vinyl; reinforced fillers such as fumed silica and precipitated silica; flame-retardant improvers, fluorescent materials and organic solvents or the like may be added, if necessary, to the addition curable silicone resin composition of the present invention within the range where the performance of the photo-semiconductor devices has not deteriorated. Furthermore, coloring by using a coloring component is also possible.

For example, the silicone resin composition of the present invention can be used for a light-emitting diode, phototransistor, photodiode, CCD, solar battery module, EPROM and photo coupler, as well as for sealing of a semiconductor element. In particular, it is preferably used for light-emitting diodes due to high transparency of the cured material.

The above sealing method may be selected as appropriate depending on types of photo-semiconductor. For curing conditions of the resin composition in the present invention, it is permissible that the temperature is approximately within the range from room temperature to 200° C., the curing time is approximately within the range from several tens of seconds to several days. In particular, however, it is preferable that the temperature is approximately within the range from 80° C. to 180° C. and the curing time is approximately within the range from one minute to ten hours.

The average particle diameter of silicon oxide filler contained in the addition cured silicone resin composition of the present invention is 1˜10 μm. However, silicon oxide filler having an average particle diameter of 1˜6 μm is preferable. In particular, the silicon oxide having a refractive index of 1.45˜1.56 is preferable. Specific examples of such silicon oxide fillers are crystalline silica fillers manufactured by Tatsumori Ltd. (Product names: Crystalite X5, Crystalite VX-S2 or the like).

The photo-semiconductor device of the present invention, which is coated and protected with the cured material of the curable silicone resin composition of the present invention, is superior in thermal resistance, moisture resistance, light stability and light emitting luminance of the device and the substrate surface is not discolored in the external environment. Therefore, the photo-semiconductor device of the present invention is a superior device in reliability and high luminosity.

Then, the present invention will be described in further detail with examples and comparative examples, but it is not limited to these. Hereafter, “part” expresses mass part, “Me” expresses methyl group and “Et” expresses ethyl group.

### <Preparation of Sealing Resin>

100 parts of terminal vinyl dimethyldephenylpolysiloxane represented by the following formula (I) (viscosity 3 Pa·s), 2.5 parts of methylhydrogenpolysiloxane represented by the following formula (II) (viscosity 15 mPa·s), 0.03 parts of chloroplatinic acid 2-ethylhexyl alcohol-modified solution (Pt concentration: 2 mass %), 0.05 parts of ethynyl cyclohexyl alcohol and 7 parts of 3-glycidoxypropyltrimethoxysilane were stirred well to prepare a silicone composition having a refractive index of 1.51.

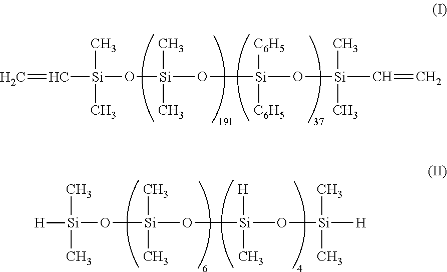

### Examples 1˜4

5 mass % of the Crystalite X5 manufactured by Tatsumori Ltd., having a refractive index of 1.55 and an average particle diameter of 1.2 μm as a silicon oxide filler, was dispersed in the above silicone composition, and then a LED package was sealed by the obtained composition to prepare Example 1. In the same way, 10 mass %, 20 mass % and 30 mass % of the above silicon oxide filler were dispersed in the above silicone composition respectively, and then a LED package was sealed by the obtained each composition to prepare Examples 2˜4.

### Examples 5˜8

5 mass % of the Crystalite VX-S2 manufactured by Tatsumori Ltd., having a refractive index of 1.55 and an average particle diameter of 5 μm as a silicon oxide filler, was dispersed in the above silicone composition, and then a LED package was sealed by the obtained composition to prepare Example 5. In the same way, 10 mass %, 20 mass % and 30 mass % of the above silicon oxide filler were dispersed in the above silicone composition respectively, and then a LED package was sealed by the obtained each composition to prepare Examples 6˜8.

### Comparative Example 1

Without using the silicone oxide filler, the LED package was sealed with the above silicone composition only to prepare Comparative Example 1.

### Comparative Examples 2˜3

40 mass % and 50 mass % of the Crystalite X5 manufactured by Tatsumori Ltd., having a refractive index of 1.55 and an average particle diameter of 1.2 μm as a silicon oxide filler, were dispersed in the above silicone composition respectively, and then a LED package was sealed by the obtained each composition to prepare Comparative Examples 2 and 3.

The curing of the above liquid silicone compositions was carried out by heating for 4 hours at 150° C. The evaluation samples of the light-emitting diode for evaluation obtained in these ways were left for 24 hours under the atmosphere of hydrogen sulfide and discoloration of Ag frame surfaces was observed using a microscope. Then, a lighting test was carried out for each sample by sending an electric current of 20 mA to the LED to measure the light-emitting brightness. The result is shown in Table 1.

TABLE 1

| | | Average light |
|---|---|---|
| | Discoloration of | emitting |
| | Ag surface | brightness (mcd) |
| Example 1 | None | 200.4 |
| Example 2 | None | 205.1 |
| Example 3 | None | 199.9 |
| Example 4 | None | 199.3 |
| Example 5 | None | 199.9 |
| Example 6 | None | 205.6 |
| Example 7 | None | 199.8 |
| Example 8 | None | 199.1 |
| Comparative | None | 180.0 |
| Example 1 | | |
| Comparative | None | 168.7 |
| Example 2 | | |
| Comparative | None | 159.3 |
| Example 3 | | |

As is clear from Table 1, concerning the discoloration of the Ag surface, there was no discoloration both in Examples and Comparative Examples, but concerning the brightness, the light emitting brightness of approximate 200 mcd in average was obtained in Examples 1˜8, whereas the light emitting brightness of 180 mcd was obtained in Comparative Example 1. In addition, in cases of Comparative Examples 2˜3, it was identified that the light emitting brightness declined much further than Comparative Example 1 wherein the filler was not dispersed.

### INDUSTRIAL APPLICABILITY

The curable silicone resin composition of the present invention, wherein not only the gas permeability is low after curing, but also the interfacial reflection is reduced, is suitable as a sealing resin for the light-emitting diode device, and the light-emitting diode obtained by using this, which has a high luminance, is suitable for general lighting. Therefore, this invention is industrially useful.

### EXPLANATION OF LETTERS OR NUMERALS

1 LED chip
2 Conductive wire
3 Silver-plated lead frame
4 Cured silicone composition
5 Mold package
6 Silicon oxide filler

What is claimed is:

1. A curable silicone resin composition used for sealing a light-emitting diode device, comprising at least a silicone resin having a refractive index of 1.50˜1.55 after curing and a silicon oxide filler having an average particle diameter of 1˜10 μm dispersed uniformly in the said silicone resin at the concentration of 1˜30 mass %.

2. The curable silicone resin composition described in claim 1 wherein a refractive index of the above silicon oxide filler is 1.50˜1.56.

3. The curable silicone resin composition described in claim 1, wherein the said silicone resin having a refractive index of 1.50˜1.55 after curing is comprised of an addition curable silicone resin composition containing (A) an organosilicon compound having a noncovalent carbon-carbon double bond, (B) organohydrogenpolysiloxane and (C) a platinum catalyst, as an essential component.

4. A light-emitting diode device (LED) comprising a premold package having a lead frame loaded with a light emitting element where the light emitting element is sealed with a sealing resin, characterized in that the above sealing resin is comprised of a resin having a refractive index of 1.50˜1.55 and a silicon oxide filler having an average particle diameter of 1˜10 μm wherein said silicon oxide filler is dispersed in the said resin having a refractive index of 1.50˜1.55 so that the concentration of the filler is 1˜30 mass % in the resin.

5. The light emitting diode device described in claim 4 wherein a refractive index of the above silicon oxide filler is 1.50˜1.56.
